(19) United States
(12) Patent Application Publication
(10) Pub. No.: US 2006/0198219 A1
(43) Pub. Date: Sep. 7, 2006

(54) Semiconductor integrated circuit device

(76) Inventors: Hirokazu Okano, Kawasaki-shi (JP); Shunichi Iwami, Sagamihara-shi (JP); Takeshi Nakano, Kawasaki-shi (JP); Atsushi Urayama, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/362,149

(22) Filed: Feb. 27, 2006

(30) Foreign Application Priority Data
Feb. 28, 2005 (JP) 2005-052748

(51) Int. Cl. G11C 7/00

(52) U.S. Cl. 365/203

(57) ABSTRACT

A semiconductor integrated circuit device is disclosed, which incorporates a mask ROM of a contact program scheme in which a drain contact of each of transistors which constitute a memory cell array is connected to a bit line through an interconnecting pattern and a via plug, wherein a plurality of via plugs are connected to a same bit line and continuously adjacently arranged in a bit line direction, a plurality of interconnecting patterns are arranged in association with the plurality of via plugs, and at least two continuously adjacent via plugs of the plurality of via plugs are commonly connected to each other by a common connecting wiring layer extending in the bit line direction through the interconnecting patterns in association with the at least two adjacent via plugs.

### CROSS-REFERENCE TO RELATED APPLICATIONS

This application is based upon and claims the benefit of priority from prior Japanese Patent Application No. 2005-052748, filed Feb. 28, 2005, the entire contents of which are incorporated herein by reference.

### BACKGROUND OF THE INVENTION

1. Field of the Invention

The present invention relates to a semiconductor integrated circuit device and, more particularly, to a semiconductor integrated circuit device on which a mask ROM employing a contact program scheme is mounted, and is applied to an application specific integrated circuit (ASIC), for example.

2. Description of the Related Art

A mask ROM mounted on an ASIC often employs a contact program scheme in which the presence/absence of a contact or an inter-wiring via is associated with “1” or “0”.

FIG. 7 schematically shows a cross sectional structure of a part of memory cell array of a mask ROM which employs a conventional contact program scheme.

In FIG. 7, an element isolation region 7 and a drain layer 8 and a source layer 6 of a cell transistor are formed in a surface layer of a semiconductor substrate 10. The source layer 6 is connected to ground potential GND. A polysilicon gate 5 is formed on the semiconductor substrate 10 through a gate insulating film 9, and a first insulating interlayer 81 is formed over the surface of the semiconductor substrate 10. The polysilicon gate 5 is a gate of the cell transistor, and is connected to a word line of the cell transistor. A contact hole is formed in the first insulating interlayer 81 in association with the drain layer 8 of the cell transistor, and a conductive contact plug 4 is embedded in the contact hole. An interconnecting pattern 3 constituted by a first metal wiring layer is formed on the first insulating interlayer 81 in association with the contact plug 4. The contact plug 4 is connected to the interconnecting pattern 3 constituted by the first metal wiring layer. A second insulating interlayer 82 is formed over the surface of the semiconductor substrate 10 including the first metal wiring layer 3 and the first insulating interlayer 81. Via holes are selectively formed in the second insulating interlayer 82 in association with respective interconnecting pattern portions 3 depending on ROM data “1” or “0” stored in each memory cell. Conductive via plugs 2 are embedded in the via holes. A bit line 1 constituted by a second metal wiring layer connected to the via plugs 2 is formed on the second insulating interlayer 82.

In FIG. 7, reference symbols Bit-A to Bit-C denote ROM data storing regions, respectively. The via plugs 2 are formed in the ROM data storing regions Bit-A and Bit-B, respectively. On the other hand, no via plug 2 is formed in the ROM data storing region Bit-C. The via plugs 2 are selectively formed depending on ROM data stored in the ROM data storing regions. In order to correctly read the ROM data from the ROM data storing regions Bit-A and Bit-B, it is necessary that both the via plugs 2 in the ROM data storing regions Bit-A and Bit-B electrically connect the interconnecting patterns 3 with the bit line 1.

In the contact program scheme described above, since one contact corresponds to 1-bit data, excellent area efficiency and a large-capacity ROM macro can be achieved. However, if only one contact is defective, the entire macro becomes defective. In particular, in a semiconductor chip on which a large-capacity mask ROM such as a system-on-chip device is mounted, the number of contacts increases in proportion to an increase in capacity of the mask ROM. Accordingly, the yield decreases. Furthermore, with the advance of micropatterning of cells in recent years, a satisfactory contact yield has been difficult to be maintained.

A semiconductor ROM using a contact program scheme which writes binary information depending on the presence/absence of connection between a diffusion layer of a transistor constituting a memory cell portion and a bit line is disclosed in Jpn. Pat. Appln. KOKAI Publication No. 9-331026.

### BRIEF SUMMARY OF THE INVENTION

According to an aspect of the present invention, there is provided a semiconductor integrated circuit device which incorporates a mask ROM of a contact program scheme in which a drain contact of each of transistors which constitute a memory cell array is connected to a bit line through an interconnecting pattern and a via plug, wherein

a plurality of via plugs are connected to a same bit line and continuously adjacently arranged in a bit line direction,

a plurality of interconnecting patterns are arranged in association with the plurality of via plugs, and

at least two continuously adjacent via plugs of the plurality of via plugs are commonly connected to each other by a common connecting wiring layer extending in the bit line direction through the interconnecting patterns in association with the at least two adjacent via plugs.

According to another aspect of the present invention, there is provided a semiconductor integrated circuit device comprising:

a semiconductor substrate;

a memory cell array constituted by a plurality of transistors formed on the semiconductor substrate;

a bit line connected to drain contacts of the plurality of transistors of the memory cell array; and

a plurality of interconnecting patterns and a plurality of via plugs which connect the drain contacts of the plurality of transistors of the memory cell array to the bit line; wherein

the plurality of via plugs are continuously adjacently arranged in a bit line direction, and

at least two adjacent via plugs of the plurality of via plugs are commonly connected to each other by a common connecting wiring layer extending in the bit line direction through the interconnecting patterns in association with the via plugs.

### BRIEF DESCRIPTION OF THE SEVERAL VIEWS OF THE DRAWING

FIG. 1 is a circuit diagram showing a frame format of a part of a memory cell array of a mask ROM which employs a contact program scheme and which is mounted on an ASIC of a semiconductor integrated circuit device according to a first embodiment of the present invention;

FIG. 2 is a plan view schematically showing a plan pattern of a part of the memory cell array shown in FIG. 1;

FIG. 3 is a cross sectional view schematically showing a part of the memory cell array shown in FIG. 1;

FIG. 4 is a circuit diagram showing a frame format of a part of a memory cell array of a mask ROM which employs a contact program scheme and which is mounted on an ASIC of a semiconductor integrated circuit device according to a second embodiment of the present invention;

FIG. 5 is a circuit diagram showing a frame format of a part of a memory cell array of a mask ROM which employs a contact program scheme and which is mounted on an ASIC of a semiconductor integrated circuit device according to a third embodiment of the present invention;

FIG. 6 is a cross sectional view of a part of a memory cell array of a mask ROM which employs a contact program scheme and which is mounted on an ASIC of a semiconductor integrated circuit device according to a fourth embodiment of the present invention; and .

FIG. 7 is a cross sectional view schematically showing a part of a memory cell array of a mask ROM which employs a conventional contact program scheme.

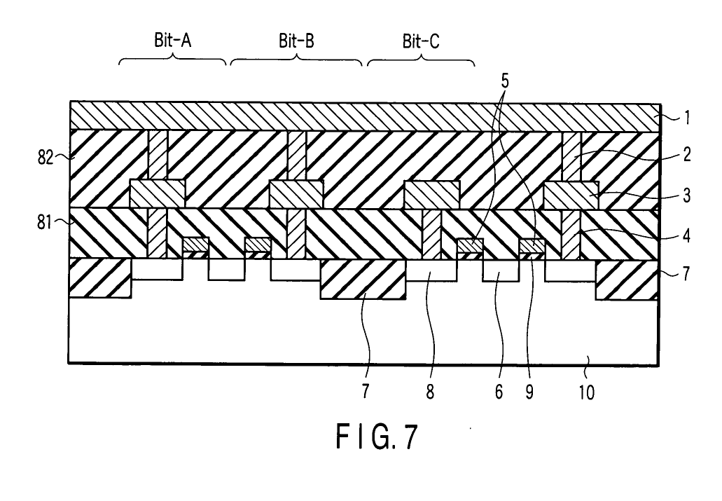

### DETAILED DESCRIPTION OF THE INVENTION

Embodiments of the present invention will be described below with reference to the accompanying drawings. In this explanation, the reference numerals common to all the drawings denote the same parts in the drawings, respectively.

### FIRST EMBODIMENT

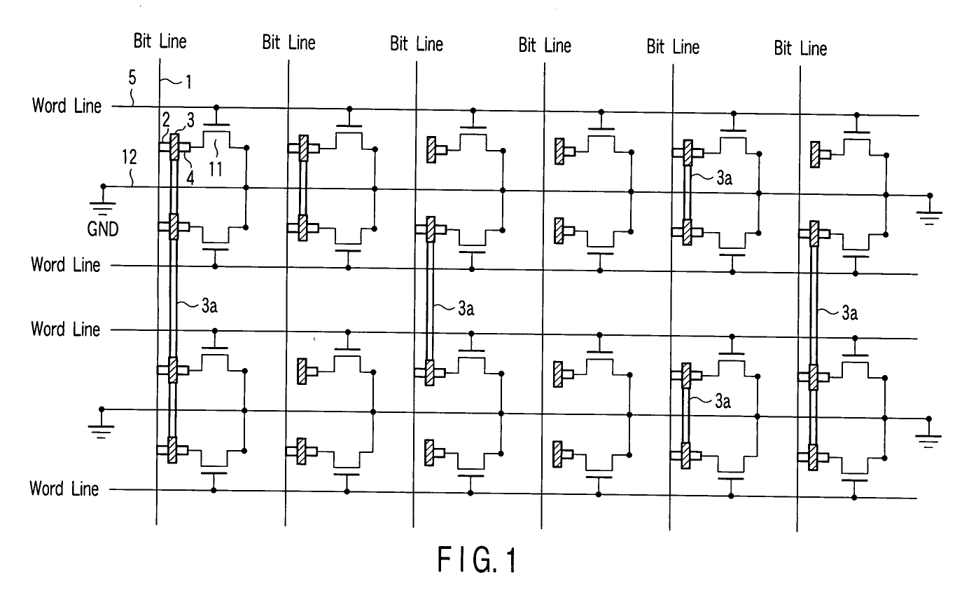

FIG. 1 is a circuit diagram showing a frame format of a part of a memory cell array of a mask ROM which employs a contact program scheme and which is mounted on an ASIC of a semiconductor integrated circuit device according to a first embodiment of the present invention.

In the memory cell array shown in FIG. 1, cell transistors (ROM cells) 11 are arranged in the form of a matrix. The sources of the cell transistors 11 are connected to a ground wiring 12. The gates of the cell transistors of the same row are commonly connected to the same word line 5. The cell transistors 11 are arranged to share a source region in the memory cell array. The cell transistors 11 are connected to ground potential GND through the shared source region.

Some of the cell transistors 11 in the memory cell array are rendered conductive upon selection. On the other hand, the remaining cell transistors 11 are rendered non-conductive upon selection. The drains of the cell transistors (in the present embodiment, the cell transistors having ROM data of “0”) which are rendered conductive upon selection are electrically connected to a bit line 1, and the drains of the remaining cell transistors (in the present embodiment, the cell transistors having ROM data of “1”) which are rendered non-conductive upon selection are set in an open circuit. The drains of the cell transistors having ROM data of “0” in the cell transistors of the same column are commonly electrically connected to the same bit line upon selection.

Furthermore, the drains of the cell transistors, continuously adjacently arranged in the bit line direction, among the plurality of cell transistors connected to the same bit line, are commonly connected to each other by a metal wiring 3a. In the present embodiment, in a memory cell array using two metal wiring layers, interconnecting patterns 3 are connected to the drains of the cell transistors through contact plugs 4 in association with the drains of the cell transistors. The interconnecting patterns 3 in association with the cell transistors having ROM data of “0” are connected to the bit line 1 through the respective via plugs 2. The interconnecting patterns 3 in association with the cell transistors, having ROM data of “0” and continuously adjacently arranged in the bit line direction, among the plurality of cell transistors connected to the same bit line, are commonly connected to each other by the metal wiring 3a arranged in the bit line direction.

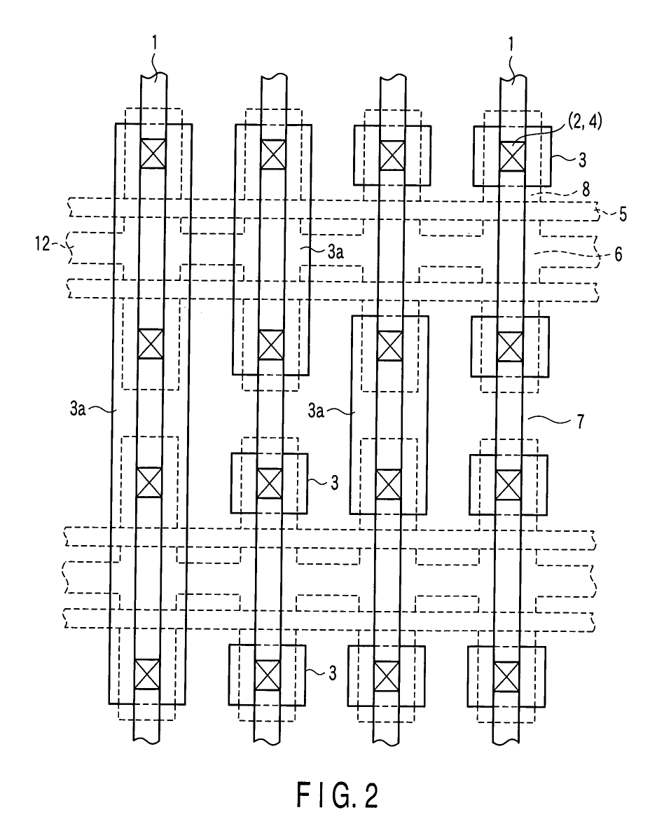

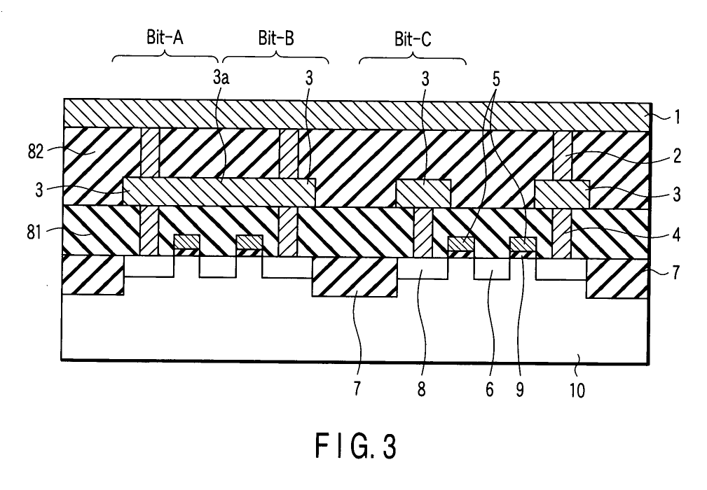

FIG. 2 schematically shows a plan pattern of a part of the memory cell array shown in FIG. 1. FIG. 3 schematically shows the cross sectional structure of a part of the memory cell array shown in FIG. 1.

In FIGS. 2 and 3, an element isolation region 7 and a drain layer 8 and a source layer 6 of a cell transistor are formed in a surface layer of a semiconductor substrate 10. The source layer 6 is connected to a ground wiring 12 (in the present embodiment, a wiring constituted by a diffusion layer). A polysilicon gate 5 is formed on the semiconductor substrate 10 through a gate insulating film 9. Furthermore, a first insulating interlayer 81 is formed over the surface layer of the semiconductor substrate 10. The polysilicon gate 5 is a gate of a cell transistor and connected to a word line of the cell transistor. Contact holes are formed in the first insulating interlayer 81 in association with the drain layers 8 of the cell transistors, and conductive contact plugs 4 are embedded in the respective contact holes. Interconnecting patterns 3 constituted by a first metal wiring layer are formed on the first insulating interlayer 81 in association with the contact plugs 4. The contact plugs 4 are connected to the interconnecting patterns 3. A second insulating interlayer 82 is formed over the surface of the semiconductor substrate 10 including the first metal wiring layer 3 and the first insulating interlayer 81. Via holes are selectively formed in the second insulating interlayer 82 in association with the interconnecting pattern portions 3 depending on ROM data “1” or “0” stored in the memory cells. Conductive via plugs 2 are embedded in the via holes. Bit line 1 constituted by a second metal wiring layer connected to the via plugs 2 are formed on the second insulating interlayer 82.

Furthermore, the drains of the cell transistors continuously adjacently arranged in the bit line direction, among the plurality of cell transistors connected to the same bit line, are commonly connected to each other by the metal wiring 3a. In the present embodiment, the interconnecting pattern portions 3 in association with the cell transistors, having ROM data “0” and continuously adjacently arranged in the bit line direction, are commonly connected to each other by the metal wiring 3a constituted by the first metal wiring layer.

In the memory cell array of a mask ROM which employs the contact program scheme according to the first embodiment having the above configuration, the plurality of via plugs connected to the same bit line are continuously adjacently arranged in the bit line direction. The plurality of via plugs continuously adjacent to each other are commonly connected by the metal wiring layer serving as a continuous layer. The interconnecting patterns 3 and the metal wiring 3a can be simultaneously formed in the same patterning step. The interconnecting pattern 3 and the metal wiring 3a constitute a continuous layer. More specifically, the interconnecting pattern 3 and the metal wiring 3a constitute a first portion and a second portion of one metal layer. The first portion and the second portion constitute a continuous layer.

With the structure, if at least one of the plurality of via plugs continuously arranged in the bit line direction is in normal connection, even if the remaining via plugs are defective in the connection, the drain layers 8 of the cell transistors in association with the connection-defective via plug can be electrically connected to the bit line through the metal wiring commonly connecting the cell transistors and the at least one connection-normal via plug. As a result, data can be normally read, and defective chips can be relieved. Thus, yield of ROMs using the contact program scheme can be increased without increasing either a memory size or the number of chip manufacture processes.

### SECOND EMBODIMENT

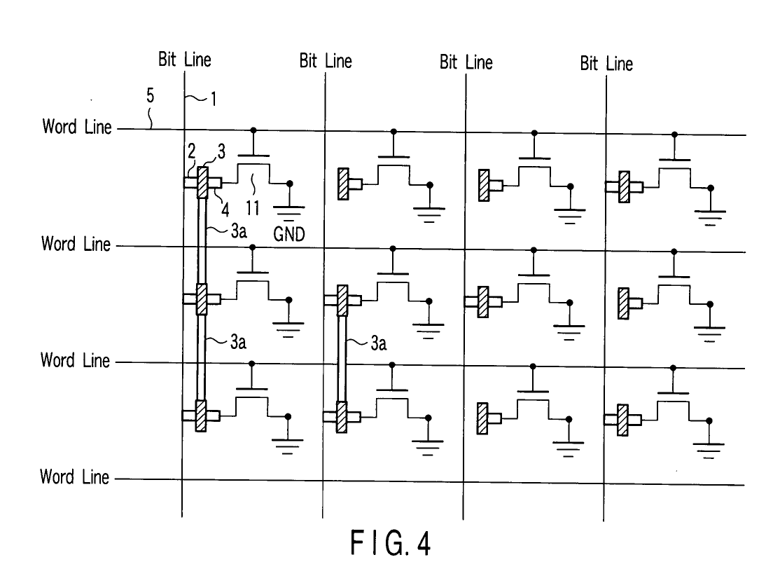

FIG. 4 is a circuit diagram showing a frame format of a part of a memory cell array of a mask ROM which employs a contact program scheme and which is mounted on an ASIC of a semiconductor integrated circuit device according to a second embodiment of the present invention.

The memory cell array shown in FIG. 4 is the same as the memory cell array described with reference to FIG. 1 except that the cell transistors are connected to ground potential GND through respective source regions. Even in the memory cell array shown in FIG. 4, the same advantages as those in the memory cell array described with reference to FIG. 1 can be obtained.

### THIRD EMBODIMENT

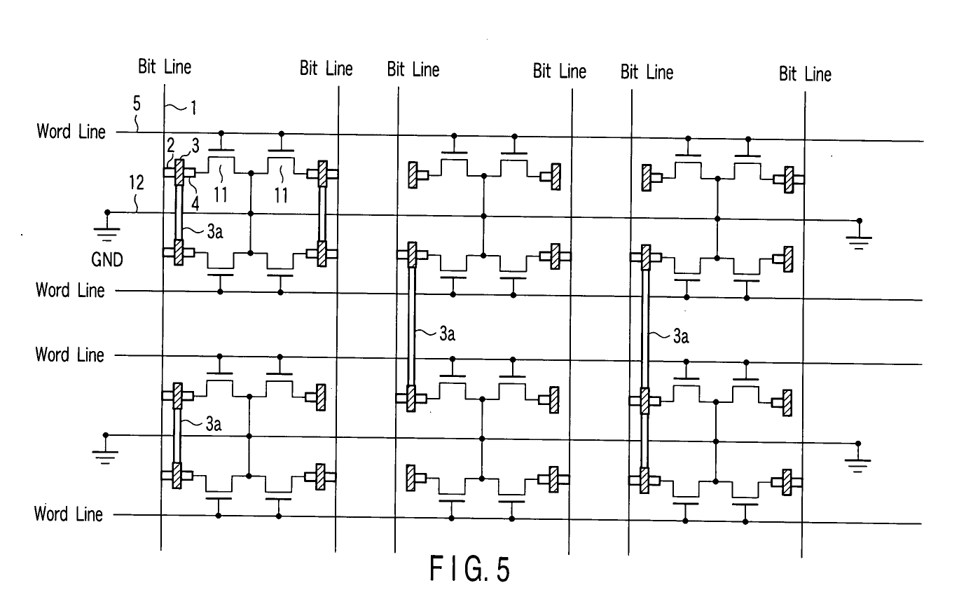

FIG. 5 is a circuit diagram showing a frame format of a part of a memory cell array of a mask ROM which employs a contact program scheme and which is mounted on an ASIC of a semiconductor integrated device according to a third embodiment of the present invention.

As shown in FIG. 5, when four or more cell transistors connected to the same bit line are continuously arranged in the bit line direction, the cell transistors are divided into a plurality of groups each having at least two cell transistors continuously arranged, and the drains of the cell transistors in each of the groups are commonly connected to each other.

In other words, in the third embodiment, when four or more via plugs are connected to the same bit line and continuously adjacent to each other in the bit line direction, the via plugs continuously adjacent to each other are divided into a plurality of groups each having at least two via plugs. The via plugs in each of the groups are commonly connected to each other by a wiring layer which is a layer continuous to the interconnecting patterns.

In the memory cell array as well, the same advantages as those in the memory cell array in the first embodiment described with reference to FIG. 1 can be obtained.

### FOURTH EMBODIMENT

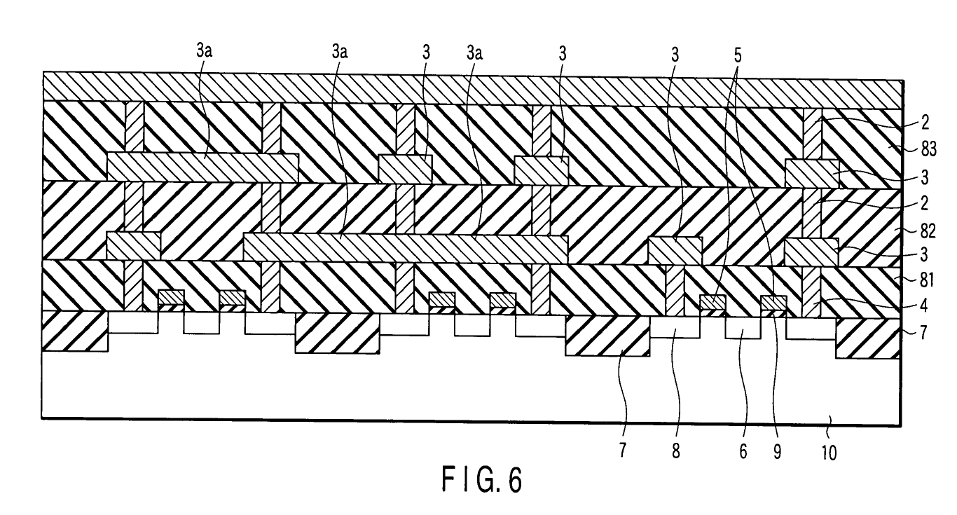

FIG. 6 is a cross sectional view showing a part of a memory cell array of a mask ROM which employs a contact program scheme and which is mounted on an ASIC of a semiconductor integrated circuit device according to a fourth embodiment of the present invention.

As shown in FIG. 6, in a memory cell array using three or more metal wiring layers, the metal wiring layers 3a each commonly connecting the interconnecting patterns 3 in association with the drains 8 of cell transistors continuously arranged in the bit line direction may be formed on different insulating interlayers of a multi-layer structure. In FIG. 6, reference numerals 81 to 83 denote first to third insulating. interlayers, reference numeral 2 denotes a via plug, and reference numeral 3 denotes an interconnecting pattern.

With this structure, the degree of freedom of the arrangement of the metal wiring layer 3a for common connection increases. For this reason, when a wiring for another application passes through between interconnecting patterns on an insulating interlayer of the multi-layer structure, the common connecting metal wiring layer may be changed to be formed on an upper or lower insulating interlayer of the multi-layer structure to avoid crossing of the wiring for the another application and the interconnecting patterns. In the memory cell array as well, the same advantages as those of the memory cell array according to the first embodiment described with reference to FIG. 1 can be obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor integrated circuit device which incorporates a mask ROM of a contact program scheme in which a drain contact of each of transistors which constitute a memory cell array is connected to a bit line through an interconnecting pattern and a via plug, wherein
a plurality of via plugs are connected to a same bit line and continuously adjacently arranged in a bit line direction,
a plurality of interconnecting patterns are arranged in association with the plurality of via plugs, and
at least two continuously adjacent via plugs of the plurality of via plugs are commonly connected to each other by a common connecting wiring layer extending in the bit line direction through the interconnecting patterns in association with the at least two adjacent via plugs.

2. The semiconductor integrated circuit device according to claim 1, wherein
the memory cell array comprises two metal wiring layers including a first metal wiring layer and a second metal wiring layer,
the interconnecting patterns is constituted by a first portion of the first metal wiring layer,
the bit line is constituted by the second metal wiring layer,
the via plug is formed between the first metal wiring layer and the second metal wiring layer, and
the common connecting wiring layer is constituted by a second portion of the first metal wiring layer, the first portion and the second portion constituting a continuous layer.

3. The semiconductor integrated circuit device according to claim 2, wherein the plurality of via plugs comprise at least three via plugs, and all of the at least three via plugs are commonly connected to each other by the common connecting wiring layer through the interconnecting patterns in association with the via plugs.

4. The semiconductor integrated circuit device according to claim 2, wherein the plurality of via plugs comprise at least four via plugs, the at least four via plugs are divided into a plurality of groups each having at least two via plugs, and the via plugs in each of the groups are commonly connected to each other by the common connecting wiring layer through the interconnecting patterns in association with the via plugs.

5. The semiconductor integrated circuit device according to claim 1, wherein
the memory cell array comprises at least three metal wiring layers,
the interconnecting pattern is constituted by a first portion of each of the metal wiring layers other than an uppermost metal wiring layer of the at least three metal wiring layers,
the bit line is constituted by the uppermost metal wiring layer,
the via plugs are formed between the at least three metal wiring layers, and
the common connecting wiring layer is constituted by a second portion of at least one metal wiring layer of the metal wiring layers other than the uppermost metal wiring layer of the at least three metal wiring layers, the first portion and the second portion constituting a continuous layer.

6. The semiconductor integrated circuit device according to claim 5, wherein
the plurality of via plugs include at least three via plugs, and all of the at least three via plugs are commonly connected to each other by the common connecting wiring layer through the interconnecting patterns corresponding to the via plugs.

7. The semiconductor integrated circuit device according to claim 5, wherein the plurality of via plugs comprise at least four via plugs, the at least four via plugs are divided into a plurality of groups each having at least two via plugs, and the via plugs in each group are commonly connected to each other by the common connecting wiring layer through the interconnecting patterns in association with the via plugs.

8. The semiconductor integrated circuit device according to claim 1, wherein sources of the plurality of transistors which constitute the memory cell array are connected to a reference voltage through a shared source region.

9. The semiconductor integrated circuit device according to claim 1, wherein sources of the plurality of transistors which constitute the memory cell array are connected to a reference voltage through respective source regions.

10. The semiconductor integrated circuit device according to claim 1, wherein the semiconductor integrated circuit device is applied to an application specific integrated circuit.

11. A semiconductor integrated circuit device comprising:
a semiconductor substrate;
a memory cell array constituted by a plurality of transistors formed on the semiconductor substrate;
a bit line connected to drain contacts of the plurality of transistors of the memory cell array; and
a plurality of interconnecting patterns and a plurality of via plugs which connect the drain contacts of the plurality of transistors of the memory cell array to the bit line; wherein
the plurality of via plugs are continuously adjacently arranged in a bit line direction, and
at least two adjacent via plugs of the plurality of via plugs are commonly connected to each other by a common connecting wiring layer extending in the bit line direction through the interconnecting patterns in association with the via plugs.

12. The semiconductor integrated circuit device according to claim 11, wherein
the memory cell array comprises two metal wiring layers including a first metal wiring layer and a second metal wiring layer,
the interconnecting pattern is constituted by a first portion of the first metal wiring layer,
the bit line is constituted by the second metal wiring layer,
the via plug is formed between the first metal wiring layer and the second metal wiring layer, and
the common connecting wiring layer is constituted by a second portion of the first metal wiring layer, the first portion and the second portion constituting a continuous layer.

13. The semiconductor integrated circuit device according to claim 12, wherein the plurality of via plugs comprise at least three via plugs, and all of the at least three via plugs are commonly connected to each other by the common connecting wiring layer through the interconnecting patterns in association with the via plugs.

14. The semiconductor integrated circuit device according to claim 12, wherein the plurality of via plugs comprise at least four via plugs, the at least four via plugs are divided into a plurality of groups each having at least two via plugs, and the via plugs in each group are commonly connected to each other by the common connecting wiring layer through the interconnecting patterns in association with the via plugs.

15. The semiconductor integrated circuit device according to claim 11, wherein
the memory cell array comprises at least three metal wiring layers,
the interconnecting pattern is constituted by a first portion of the plurality of metal wiring layers except for an uppermost layer of the at least three metal wiring layers,
the bit line is constituted by the uppermost metal wiring layer,
the via plugs are formed between the at least three metal wiring layers, and
the common connecting wiring layer is constituted by a second portion of at least one metal wiring layer of the plurality of metal wiring layers except for the uppermost layer of the plurality of metal wiring layers, the first portion and the second portion constituting a continuous layer.

16. The semiconductor integrated circuit device according to claim 15, wherein the plurality of via plugs comprise at least three via plugs, and all of the at least three via plugs are commonly to each other connected by the common connecting wiring layer through the interconnecting patterns in association with the via plugs.

17. The semiconductor integrated circuit device according to claim 15, wherein the plurality of via plugs comprise at least four via plugs, the at least four via plugs are divided into a plurality of groups each having at least two via plugs, and the via plugs in each group are commonly connected to each other by the common connecting wiring layer through the interconnecting patterns in association with the via plugs.

18. The semiconductor integrated circuit device according to claim 11, wherein the sources of the plurality of transistors which constitute the memory cell array are connected to a reference voltage through a shared source region.

19. The semiconductor integrated circuit device according to claim 11, wherein sources of the plurality of transistors which constitute the memory cell array are connected to a reference voltage through respective source regions.

20. The semiconductor integrated circuit device according to claim 11, wherein the semiconductor integrated circuit device is applied to an application specific integrated circuit.
